(19) United States
(12) Patent Application Publication
(10) Pub. No.: US 2008/0278565 A1
(43) Pub. Date: Nov. 13, 2008

(54) Printing with Laser Activation

(76) Inventors: John Haig Marsh, Glasgow (GB); Stephen Gorton, Edinburgh (GB); Gary Ternent, North Lanarkshire (GB); Christopher Humby, Glasgow (GB); Eric Goutain, Cranbury, NJ (US); Alexander Ballantyne, Edinburgh (GB)

Correspondence Address: MCCARTER & ENGLISH , LLP STAMFORD OFFICE, FINANCIAL CENTRE , SUITE 304A, 695 EAST MAIN STREET, STAMFORD, CT, 06901-2138, US

(21) Appl. No.: 11/596,902

(22) PCT Filed: May 19, 2005
(86) PCT No.: PCT/GB2005/001898

§ 371 Date: Apr. 9, 2008

(30) Foreign Application Priority Data
May 19, 2004 (GB) 0411130.8

(51) Int. Cl. B41J 2/47; H01S 5/00

(52) U.S. Cl. 347/237; 372/50.12

(57) ABSTRACT

Methods and apparatus for implementing thermal printing techniques onto thermally sensitive print media use one or more laser arrays to provide optical heating. Thermal management of the laser arrays is described. Techniques for alignment of multiple monolithic arrays onto a common carrier are described. Various output optics are described.

The present invention relates to printing methods and devices in which semiconductor lasers are used to effect activation of a thermally or optically sensitive print medium in order to form printed images on the medium.

Thermally sensitive print media (e.g. ‘thermal papers’) are widely used in a number of applications, for example in printing cash till receipts, labels, forms etc, particularly in specialist printing devices, and more generally in any application where any small cost penalty of using thermally sensitive print media rather than ‘plain paper’ printing is not an issue.

The conventional technique for applying localised heat to the thermally sensitive print medium has been by way of small resistive heating elements formed in a linear array and applied to the surface of a thermal paper as the paper passes over the print head. More recently, it has been proposed to use an array of semiconductor lasers to provide the localised heating to the thermal paper by way of optical energy. The optical energy delivered to the thermally sensitive print media results in the formation of a mark, or image, on the media in the same manner as in conventional direct heating techniques, according to the construction of the print media.

There are several advantages in using laser heating of the print media. Because the energy is delivered by way of an optical beam, no contact between the print head and the print media is necessary. Thus, printing on coarser paper surfaces is possible, rather than the ‘shiny’ or smooth surfaced print media typically required in conventional thermal printing systems. Non-contact print heads also offer the opportunities for reduced print head wear and reduced print head cleaning schedules.

Semiconductor lasers can be configured to produce a range of possible optical spot sizes and shapes according to the desired format of the printed ‘dots’ on the print media. Semiconductor lasers can also be conveniently electrically controlled to yield the required print images as the print media pass the print head. Semiconductor lasers can also be formed in arrays of parallel lasers on a single monolithic substrate such that multiple separately addressable laser spots can be generated by each laser array, and multiple adjacent arrays can be positioned on a carrier so that wide print heads can be fabricated.

There are a number of problems in implementing arrays of lasers for use as print heads for thermal print media. Broadly speaking, these problems fall into three categories.

### 1. Thermal Management

The optical output of semiconductor lasers is affected by the operating temperature. In order to control the optical output, the operating temperature of the laser arrays, and indeed of the individual lasers within an array, must be either controlled to provide stable output characteristics, or must be known and compensated for with the laser drive currents in order to provide predictable output characteristics.

### 2. Array Mounting and Alignment

To provide wide print heads, it is necessary to provide a large number of parallel lasers in an array. In a single monolithic laser array, it presently proves to be disadvantageous to fabricate more than a few tens of lasers on each substrate for several reasons. Firstly, the yield falls with increasing number of laser elements, making large arrays significantly more expensive. Secondly, the larger the array, the greater the difficulties in maintaining consistent output performance from each laser in the array, e.g. because of temperature profiles across the array. Thus, it is preferred to fabricate smaller arrays (e.g. of sixteen lasers) and then to mount multiple arrays onto a single carrier. This presents a number of problems relating to alignment of the arrays so that the laser spots from adjacent arrays are very precisely positioned relative to one another. The human eye is very sensitive to small irregularities in spacing of dots in an otherwise regular array of dots, so that individual arrays must be precisely registered to one another.

### 3. Output Optics

In laser spot formation, many factors affect the beam profile or beam shape and thus the laser spot. When using laser arrays for thermal printing techniques, not only is accurate spot alignment important, but also the cross-sectional profile of the beam at the image plane (i.e. the plane of the thermal print media) also should be controlled to provide a consistent and specific form of spot. This may be achieved in a number of ways, including by way of specific optical output elements for focussing or waveguiding.

The present invention seeks to overcome a number of the problems associated with the above.

Aspects of the present invention are defined in the accompanying independent claims. Further preferred features are defined in the dependent claims.

Embodiments of the present invention will now be described by way of example and with reference to the accompanying drawings in which:

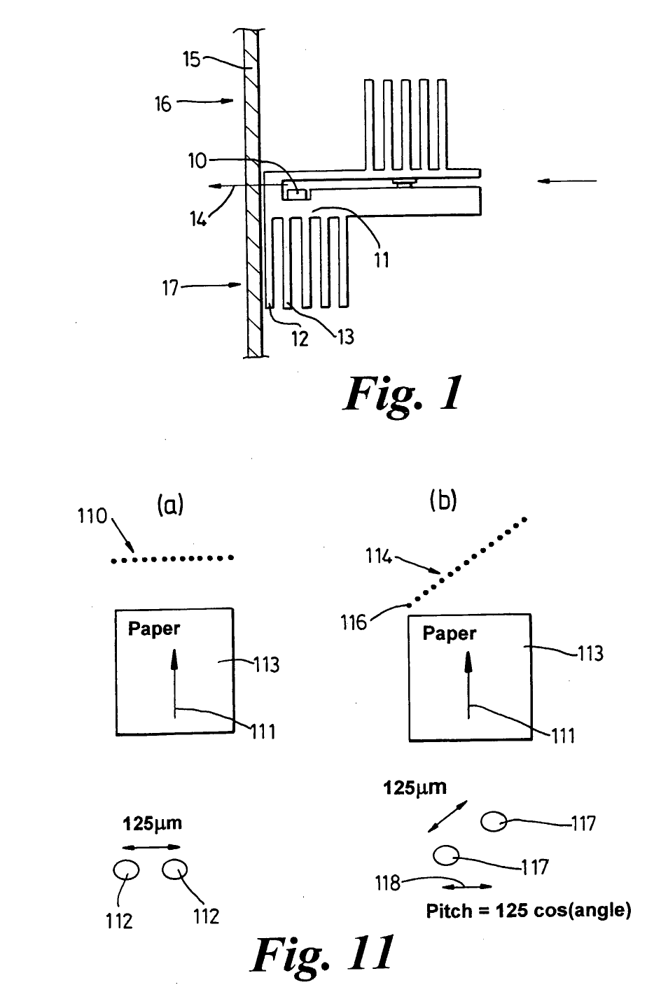

FIG. 1 shows a schematic cross-sectional side view of a laser print head and paper transport path;

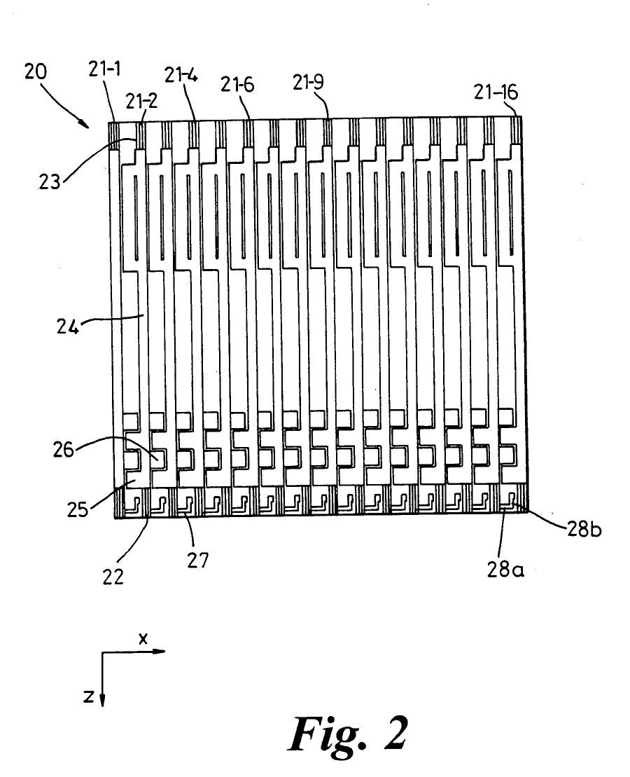

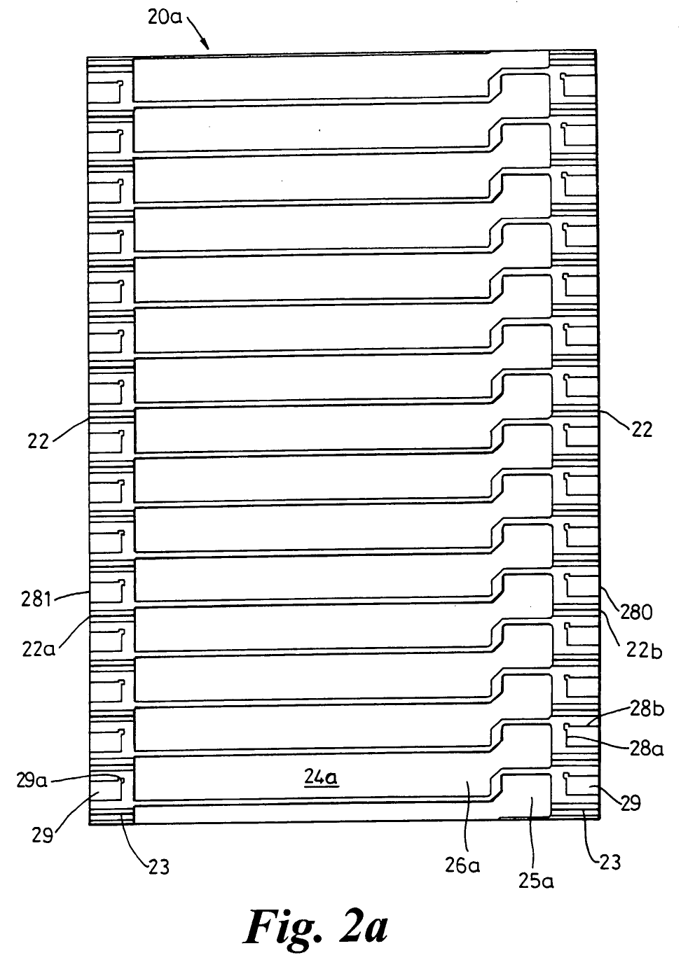

FIG. 2 shows a plan view of a monolithic laser array suitable for use in a print head, also illustrating a first alignment fiducial configuration;

FIG. 2a shows a plan view of an alternative monolithic array suitable for use in a print head, also illustrating a second alignment fiducial configuration;

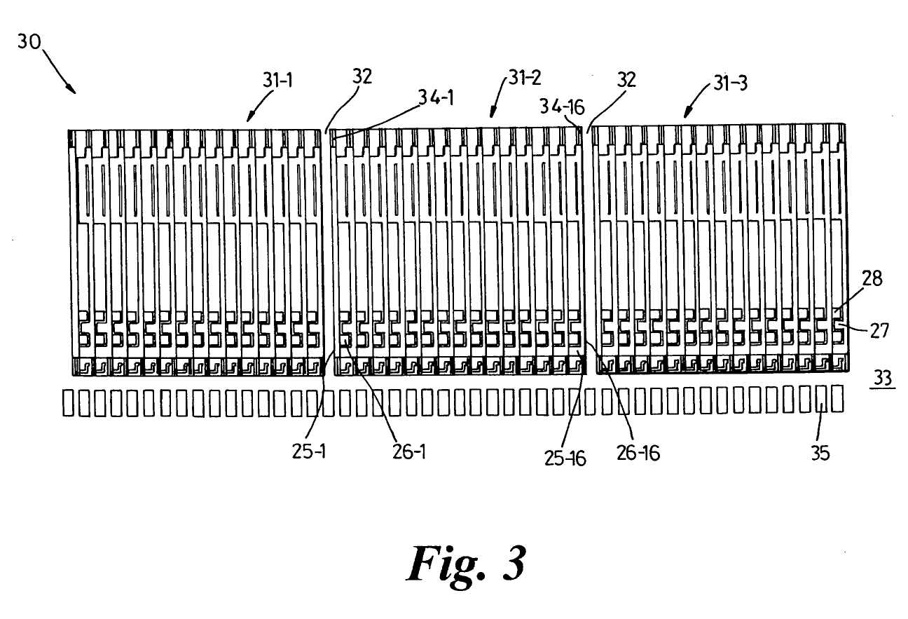

FIG. 3 shows a plan view of a compound array formed from a series of the monolithic laser arrays of FIG. 2 on a carrier;

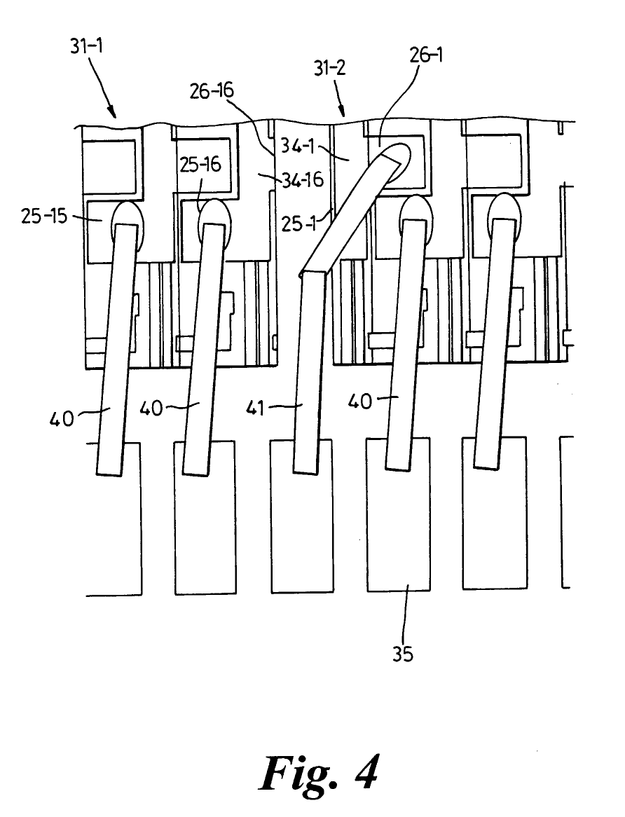

FIG. 4 shows a magnified plan view of a part of the compound array of FIG. 3 showing wire bond configuration;

FIG. 5 shows a cross-sectional end view of a compound array during the solder bond process for attaching the laser arrays to the carrier;

FIG. 6 shows a schematic block diagram of a print head having a laser array that includes means for individually modulating laser element outputs according to a desired characteristic;

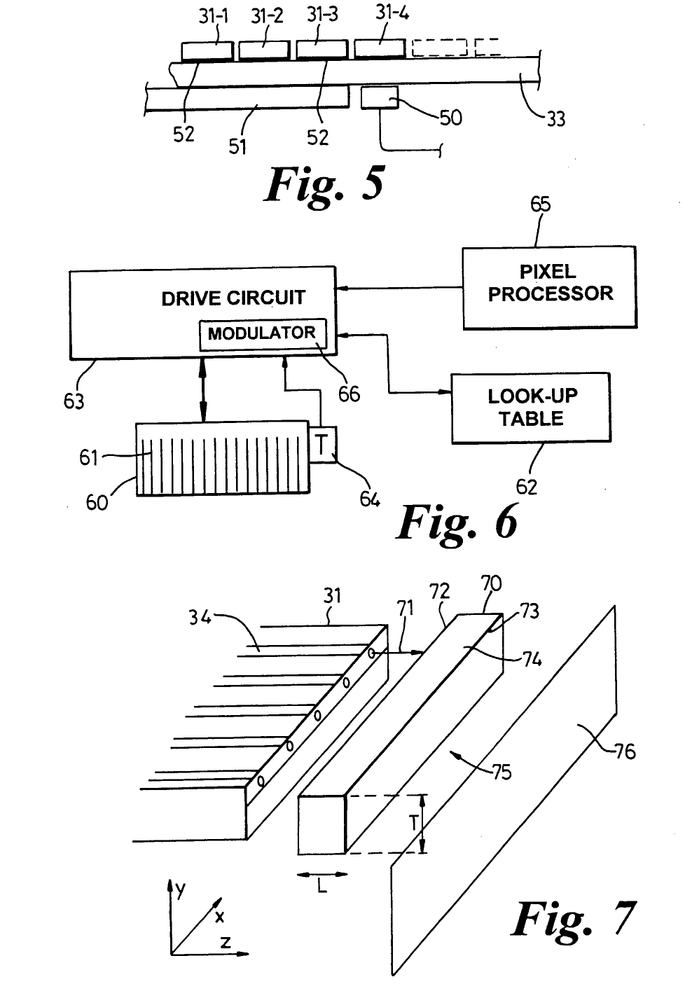

FIG. 7 shows a schematic perspective view of a laser array for use in a print head having an output waveguide for controlling spot aspect ratio;

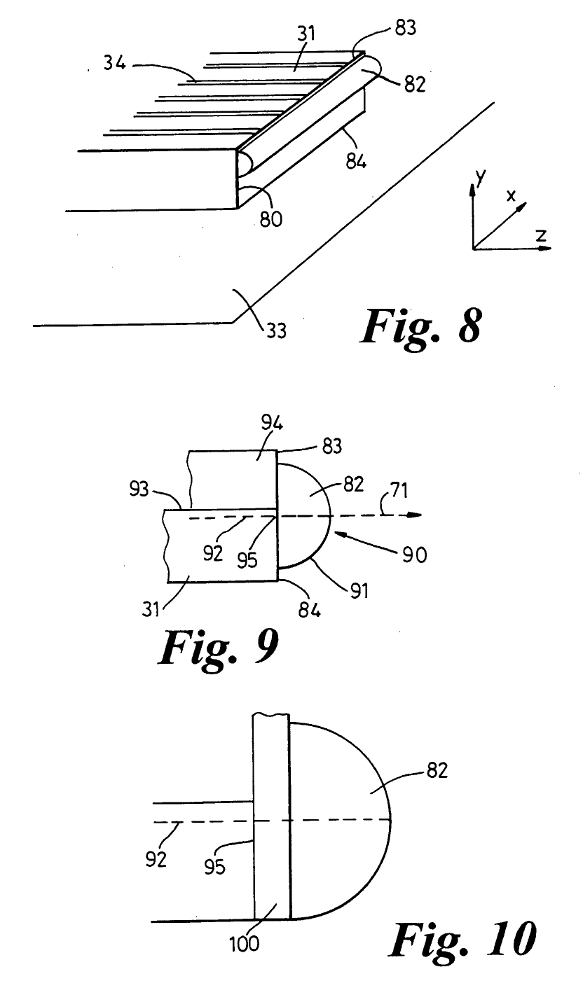

FIG. 8 shows a schematic perspective view of a laser array having a bead lens on the output facet;

FIG. 9 shows a schematic cross-sectional side view of a laser array having a bead lens on the output facet, the positioning of which is determined in part by an array and a top surface mounted glass block;

FIG. 10 shows a schematic cross-sectional side view of a laser array having a bead lens on a glass window forming the output facet of the laser array;

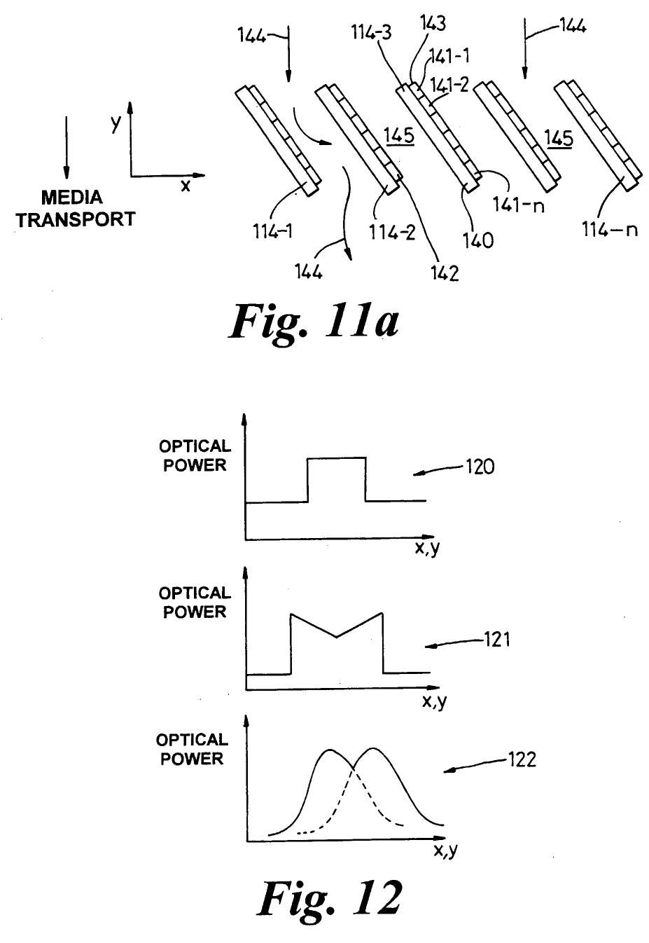

FIG. 11 shows schematic views of paper transport relative to laser arrays for reducing printed dot pitch;

FIG. 11a shows a schematic view of a tilted array configuration for a print head;

FIG. 12 shows schematic views of several laser beam intensity profiles as a function of x and/or y across the beam axis; and

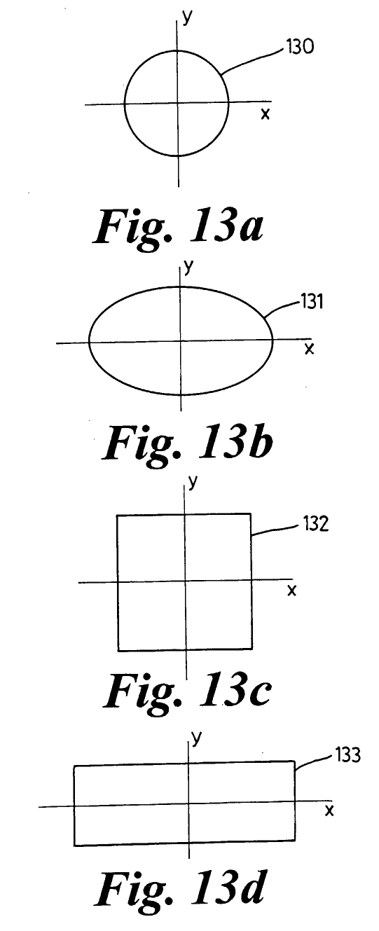

FIGS. 13a to 13d show various preferred beam spot profiles.

Exemplary embodiments of the present invention are described particularly with reference to the use of semiconductor lasers for activating thermally sensitive print media in order to form printed images on the print media. However, it will be noted that the techniques and devices described herein can also be used with optically sensitive print media, i.e. print media that is directly optically activated rather than, or as well as, thermally activated to produce the printed image.

The present specification refers to arrays of ‘semiconductor lasers’. It is intended that this expression also encompasses any other semiconductor devices that can generate a focusable or concentrated optical output of sufficient intensity and spot size that they can be used in the thermal and/or optical printing techniques as described herein.

The expressions ‘print medium’ or ‘print media’ are intended to encompass all forms of thermally sensitive media in which localised heating results in the formation of a defined mark, or image, on the media whether by use of heat sensitive inks incorporated within the paper or otherwise. The expressions ‘print medium’ or ‘print media’ are also intended to encompass all forms of optically sensitive media in which direct optical activation results in the formation of a defined mark, or image, on the media whether by use of optically sensitive inks incorporated within the paper or otherwise. A combination of thermal and optical activation is also envisaged. It is also intended that the defined marks encompass not only visible markings but also marks that are not necessarily visible to the naked eye, but e.g. visible only in the ultraviolet spectrum.

### Thermal Management of the Print Head

In normal operation, laser arrays generate significant quantities of heat that can reduce their efficiency, and affect the controllability and stability of optical output. In order to maintain efficient operation, it is desirable to efficiently conduct heat away from the laser arrays to maintain acceptably low array temperatures. Conventionally, this can be done with a heat sink thermally coupled to the laser array, and an active thermal transfer mechanism such as a fan, a thermo-electric cooler or liquid heat pipe.

In the present invention, to increase the effectiveness of the heat sinking, the print medium itself is used to carry away excess heat from the laser array. With reference to FIG. 1, the laser array 10 is mounted on a heat sink 11. The heat sink includes one or more thermal dissipation elements (e.g. fins 12, 13) that extend laterally to the direction of laser output 14.

A paper transport mechanism (not shown) is provided to transport the paper 15 (or other print media) along a transport path that passes the optical output of the laser array 10. The transport path comprises an upstream portion 16 (before the paper reaches the laser beam 14), and a downstream portion 17 (after the paper has passed the laser beam).

The heat sink 11 extends in the downstream direction along the downstream paper path 17. Preferably, at least one of the thermal dissipation elements 12 forms a paper guide so that the paper 15 is in direct contact with the element 12 for maximum heat transfer. However, the paper path may be configured such that the paper is very close to (i.e. in close thermal association with) the heat sink element 12 such that significant heat transfer can take place.

The proximity of the heat sink 11 to the paper 15 thereby allows for either a contact or non-contact (conductive or radiative) method of moving heat away from the heat sink. Because the paper is, of necessity, quite thermally conductive it absorbs heat well from the heat sink, and carries that thermal energy away from the area of the print head as it travels along the transport path.

### Laser Array Mounting and Alignment

To provide a wide print head capable of printing many ‘dots’ simultaneously, it is necessary to mount a number of laser arrays onto a single carrier with a high degree of registration accuracy. With existing yields, it is economic to manufacture monolithic laser arrays comprising sixteen lasers per chip, so that each chip provides sixteen laser spots for printing up to sixteen dots simultaneously. However, it is desirable to provide print heads much wider than this, preferably up to 64 array elements wide or more. Even if yields for individual monolithic arrays rise, there are still practical difficulties in producing very wide print heads since the maximum dimension of a monolithic laser array would, in any event, be limited by the maximum size of semiconductor substrates available (e.g. 150 mm for GaAs substrates).

In the present invention, multiple monolithic arrays are mounted onto a common carrier such that ‘wide laser arrays’ are formed. For convenience—where distinction is required—we shall refer to an array comprising multiple monolithic arrays as a ‘compound array’. Typical thermal printing requirements are for 203 dpi (dots per inch) or 8 dots per mm which means that lasers in the array must be at 125 microns pitch. Other standard pitches are also widely used, such as 250 dpi, 300 dpi, 600 dpi and 1200 dpi. Exemplary embodiments described hereinafter illustrate 203 dpi. These pitches are readily achievable within a single monolithic array formed using conventional photolithography processes. However, these pitches cause a number of problems when forming a wide compound array from separate monolithic arrays. There are several reasons for this.

Firstly, available semiconductor wafer cleave processes are sufficiently inaccurate and produce sufficiently coarse chip ‘edges’ that the ability to position adjacent chips (monolithic arrays) adjacent to one another can be compromised. Secondly, currently available chip positioning and surface mount technology does not readily admit such precise positioning of multiple chips on a single carrier such that continuation of the required pitch of lasers is accurately maintained across all the monolithic arrays in the ‘compound array’.

With reference to FIG. 2, there is shown a monolithic semiconductor laser array 20, suitable for use in forming a wide print head laser compound array, each array 20 comprising sixteen laser elements 21-1, 21-2 . . . 21-16 each having an optical output facet 22 such that sixteen parallel output beams may be provided. Each laser element 21 comprises an optical waveguide 23, only the passive portion of which is visible, the active portion being concealed beneath a layer of metallization 24 which forms the drive contact for the laser. The waveguide 23 may be a ridge waveguide in which case the drive contact extends along the ridge (e.g. as shown in the narrow portion of metallization at 24).

The drive contact metallization 24 also includes a first bond pad area 25 off-waveguide and located near one edge of the array for making wire bond attachments in accordance with normal wire bond techniques. In accordance with one aspect of the invention, a second bond pad area 26 is included off-waveguide but on the opposite side of the waveguide 23 to the first bond pad area 25. It will be noted that the second bond pad area 26 of the laser element 21-2 effectively encroaches onto the rectangular semiconductor area otherwise occupied by the adjacent laser element 21-3.

Each laser element also includes an alignment fiducial 27 disposed proximal to the output end of the laser element 21. The alignment fiducial 27 preferably comprises a visible alignment edge in two orthogonal directions, e.g. one alignment edge 28a in the x-direction and one edge 28b in the z-direction as shown, the z-direction being the optical axis and the x-direction being the array width. The alignment fiducials 27 are formed using any suitable photolithographic process during fabrication of the laser array. Preferably, the fiducials 27 are formed as an etched step in the substrate which can be formed at the same time, and using the same photolithography mask, as for defining the waveguide 23 ridge, where the lasers 21 are of the ridge waveguide type. This ensures that the fiducial is precisely registered to the waveguide x-position, and is also precisely aligned with the optical axis.

The fiducial pattern therefore preferably provides features having parallelism with the waveguide and perpendicularity with the waveguide. A preferred arrangement has a 5 micron etched step as the alignment edges created in a ridge etch layer.

The fiducials allow for an accurate die placement on a carrier, and enable the use of known ‘cross hair generator systems’ to align the die instead of an expensive image recognition system. This allows for a more cost efficient assembly method.

With reference to FIG. 3, a compound array 30 of individual monolithic laser arrays 31-1, 31-2, and 31-3 is shown. Critical to the assembly of a compound array is that the laser element pitch must be maintained across the gaps 32 between adjacent arrays 31. This is problematic because the wafer cleave process results in ‘untidy’ or poorly defined edges of individual die. The cleave lines, and therefore die edges may be any one or more of (i) non-parallel to the laser axes, (ii) non-orthogonal to the plane of the die; (iii) non-straight (i.e. non-linear) and (iv) non-planar (i.e. not flat edges). Furthermore, the die edges may be an indeterminate distance from the optical axis of the first laser 21-1 (or 21-16) of the array.

The existence of a fiducial 27 greatly assists in accurate relative placement of each successive array 31 in the compound array 30 relative to a carrier substrate 33. Each array may be positioned relative to reference marks on the carrier 33, or to fiducials on another array.

However, it has been discovered that the human eye is far more highly sensitive to single discontinuities in the pitch of printed dots caused by misalignment of adjacent arrays than to a gradual change in pitch or to departure of laser position relative to an initial grid across a wide array. In other words, it has been discovered to be far more important to ensure that the relative spacing of any two adjacent die 31 is as close as possible to the required laser element pitch than it is to control overall run-out in tolerances between arrays over the whole compound array. The quality of printed text has been found to be relatively unaffected by cumulative run out across the arrays 31 but far more significantly affected by adjacent die misalignment.

Therefore, it is preferred that, during die positioning on the carrier substrate 33, each die 31 is aligned and positioned relative to the immediately adjacent array and not to a single reference mark on the carrier and not to a single initial array 31. Thus, in a preferred method, the first die 31-1 is positioned and aligned relative to a reference mark on the carrier so that it is square to the front and side edges in a nominal position. The second array 31-2 is then positioned and aligned relative to the first array 31-1. The third array 31-3 is then positioned and aligned relative to the second array 31-2. Each subsequent array will be positioned and aligned relative to the immediately preceding array on the carrier 33. For clarity, the expression ‘positioning’ is intended to encompass relative placement of a die in the x-z plane (i.e. in the plane of the carrier surface) and the expression ‘alignment’ is intended to encompass angular presentation of the die in the x-z plane (i.e. rotation relative to the plane of the carrier surface).

This approach also allows for a smaller field of view to be used in the die placement equipment, which simplifies the system.

With further reference to FIG. 3, it will be noted that each array 31 has been cleaved from a wafer such that the cleave cuts through the first bond pad area 25-1 of the laser element 34-1 of array 31-2 and the other cleave cuts through the second bond pad area 26-16 of the laser element 34-16. However, the laser element 34-1 has a surviving (second) bond pad area 26-1 and the laser element 34-16 has a surviving (first) bond pad area 25-16.

This provides several advantages. Firstly, it will be noted that the cleave may be effected anywhere in a substantial part of the width of the bond pad areas and secondly, a substantial part of the width of one laser element may be sacrificed at one edge of the array without affecting the function of that element. Therefore, adjacent arrays may be positioned next to each other with a substantial spacing while still ensuring that it is possible to maintain the pitch of laser elements across adjacent arrays.

In the preferred embodiments, where a 125 micron pitch is sought, the bond pads are typically 80 microns wide, and this allows a spacing between arrays of up to 75 microns while still maintaining the 125 micron pitch, and still allowing a useful margin for variability in the cleave process.

Referring now to FIG. 4, the wire bond arrangements are shown. The relevant corners of adjacent array dies 31-1 and 31-2 are shown. Laser element 34-1 of array 31-2 and laser element 34-16 of array 31-1 are the edge elements. Element 34-16 has lost its second bond pad area 26-16. This does not matter because the first bond pad areas 25 are being used for most laser elements.

Laser element 34-1 has lost its first bond pad area 25-1 but this does not matter because electrical contact to the drive contact can still be effected using the second bond pad area 26-1. Conventional wire bonds 40 are used for laser elements except those where the second bond pad areas 26 must be used. In these cases, a dog-leg or s-shape wire bond 41 is used.

In this manner, a regular pattern of wire bond points 35 on the carrier 33 can be used without interfering with the regular pitch of the lasers in successive arrays 31. Although the arrangement of FIG. 4 shows use of straight wire bonds 40 to each of the near (first) bond pad areas 25 and use of the dog-leg or s-shape wire bonds 41 to the far (second) bond pad areas 26, it will be understood that this arrangement can be reversed. In other words, the second bond pad areas 26 may be used for the majority of wire bonds using straight wire bonds 40 for the longer reach, and the first bond pad areas 25 may be used at each end only for a shorter reach dog-leg wire bond 41.

As discussed above, the gap between adjacent arrays 31 is critical. Any gap which increases the laser pitch between arrays is to be avoided. A 5 micron gap may be detected by the human eye in a block of black text. Maintaining less than a 5 micron gap between arrays is difficult and expensive, requiring superb array edge tolerances and a 1 micron accuracy placement system. The present invention allows the array edge tolerances and placement accuracy of the system to be relaxed. The double bond pad structure described above means that standard scribe and cleave tolerances can be accommodated.

In the preferred arrangement shown, all of the laser elements in the monolithic array are provided with double bond pads, but it will be noted that only the laser element at the relevant lateral edge of the array (e.g. element 34-1) need be provided with the second bond pad 26-1.

The bond pads are formed using an appropriate mask design which also provides separate test pads 27, 28 (FIG. 3) for bar test probing, without risk of damage to the wire bond pads.

Various patterns of bond pad areas, fiducials and other metallization areas may be used. FIG. 2a illustrates an alternative arrangement in which the drive contact metallization area 24a is laterally coextensive with the second bond pad area 26a extending from one side of the waveguide 23, while the first bond pad area 25a extends laterally beyond the other side of waveguide. This arrangement may be used with ridge waveguides in which the metallization extends off the ridge, but is also particularly useful for buried heterostructures waveguides without a ridge.

FIG. 2a also illustrates an alternative fiducial 29. This fiducial also provides one alignment edge 28a in the x-direction and one alignment edge 28b in the z-direction with an identification feature 29a. An important difference is that the fiducial 29 extends in the z-direction across the cleave boundary between adjacent devices formed on the same substrate. Thus, upon cleave of individual arrays 20a from a substrate, each fiducial 29 is severed leaving a cleaved edge 280, 281 (having a counterpart on the adjacent die). This is found to be particularly useful because the high contrast material of the fiducial provides a clear demarcation of the location of the plane of the laser facets 22. This allows even more precise positioning of the laser arrays 20a on a carrier with respect to the z-axis (optical axis). This can be very important in maintaining precise beam shape control. In other words, the cleaved fiducial provides very accurate determination of z position of the laser facets.

Thus, in a general aspect, the laser array 20 includes a fiducial mark 29 on one or more of the laser elements 21 which fiducial mark has a first reference or alignment edge 28a extending in a direction that is transverse (preferably orthogonal) to the optical axis of the laser element 21 and a second reference or alignment edge 28b extending in a direction that is parallel to the optical axis of the laser element 21. The fiducial mark extends across the cleave zone or boundary of the array such that, after cleave of the array from a wafer substrate, the fiducial mark 29 extends right to the laser element facet 280, 281 and therefore accurately marks the cleave plane.

Preferably, a fiducial mark 29 is provided proximal to each end of the laser element 21 as shown in FIG. 2a (i.e. near to both the front facet 22a and the rear facet 22b) so that accurate angular presentation of the array in the x-z plane can be determined by comparison of the relative position of the two fiducials. Alternatively or in addition, a fiducial mark is provided on at least two laser elements separated across the array for the same reason. More preferably, each laser element in the array includes such a fiducial mark.

The larger area of fiducial mark shown in FIG. 2a also provides for greater adhesion of a metal fiducial over a cleave boundary. During the cleave operation, thin fiducial marks in a metal layer may have a tendency to delaminate or tear. Metal fiducials generally have a higher contrast and visibility useful in the alignment operation. Metal fiducials may be formed using the same photolithographic and etch steps that form a drive contact of the laser element.

Laser arrays as described above are preferably fabricated using GaAs semiconductor substrates. Conventionally, GaAs die are soldered to a carrier with eutectic solder (e.g. AuSn, InPbAg) which gives good thermal and electrical conduction while matching to the coefficient of thermal expansion of the carrier. If a further component needs to be placed in the same area, a solder of lower melting point can be used for the second components, which keeps the second reflow temperature low enough not to reflow the first solder joint. If the first solder joint was reflowed for a second time, then the component would move and also more gold would be dissolved into the solder joint from the carrier/die metallization (which may lead to gold embrittlement of the joint and reliability problems). Movement of a previously soldered component would be severely problematic when precise positioning and alignment of laser arrays is critical.

Thus, several solders can be used in a “solder hierarchy” to solder down several successive components onto a carrier. However, for very large compound arrays (e.g. incorporating tens of monolithic arrays 31), there may be more die to solder down than there are different reflow temperature solders to accommodate. Hence a solder hierarchy cannot be used effectively or efficiently for large compound arrays without risk of array movement or solder joint embrittlement. Compound arrays of up to 40 or 80 monolithic arrays 31 on a single carrier 33 are envisaged.

One alternative is to use a special fixture to hold all arrays 31 in position and to reflow them all with the same solder at the same time. Such a process and fixture is very difficult to achieve successfully without movement which would impair the precise alignment of arrays required, or without damage to the arrays. Therefore, in a preferred arrangement, rather than a solder joint, an electrically and/or thermally conductive adhesive is used that is thermosetting. Such thermosetting adhesive may be in the form of a viscous liquid or film adhesive. The thermosetting process is non-reversible so that successive heat cycles applied to adhere further arrays to the carrier will not disturb previously bonded arrays. A thin layer of thermosetting adhesive is used to mount each array followed by in situ curing of the adhesive prior to the next component attach. When the subsequent array is then heated to cure the adhesive, the previous adhesive joint will not reflow and the die will not move.

Exemplary thermosetting adhesives include Epotek H20E, Epotek 353ND, Epotek H70E, Ablebond 84-ILMi, Loctite 3873, Tra-Duct 2958. Exemplary thermosetting films include Ablefilm ECF561 and Ablefilm 5015.

An alternative approach to using thermosetting adhesives as discussed above is to locally control the temperature of the carrier during the solder operation. In this approach, temperature control device is used to limit the number of temperature excursions seen by each array solder joint.

With reference to FIG. 5, in this approach, the carrier 33 is formed from a suitable thermally conductive material, such as CuW. A thin heater element 50 is placed under the CuW carrier to locally heat only a small region of the carrier corresponding to the array 31-4 being solder bonded. Arrays 31-1, 31-2 and 31-3 have already been positioned and bonded. The small heated region is preferably only enough to reflow the solder of the array being placed and sufficiently localised that previously bonded neighbouring arrays are not significantly affected. In a further improvement, a cold plate 51 is positioned under the CuW carrier in the neighbouring area underlying previously solder-bonded arrays 31-1 . . . 31-3. In this way, the heated region may be confined.

In this way, number of times that the eutectic solder 52 under each array 31 is reflowed is minimised. By limiting the number of times each solder joint reflows to two or three times, the eutectic solder 52 will not dissolve too much gold from the surrounding metallization to cause embrittlement. The movement of arrays can be kept to a minimum by using a pick-up tool or custom fixture to hold the neighbouring arrays at the same time as the array being placed. Such a tool or fixture need hold only two or three arrays at a time to limit their movement, as the remainder of the arrays will be cooler and the solder will not reflow. This tool or fixture, being limited in its extent, is much easier to make and control than an equivalent fixture that would hold tens of arrays at the same time.

Preferably, the heater 50 is sufficiently localised and the cooling device 51 is sufficiently powerful that the number of reflows could be limited to one—i.e. the initial placement. The cooling device may be an electrically cooled (e.g. Peltier device) or a water cooled chuck, with a heater at one edge or in a recess in the chuck, the carrier 33 being moved relative to the chuck as the successive arrays are placed.

In a general aspect, the heating device is placed in proximity to the device being solder bonded at the same time that the cooling device is positioned in proximity to one or more of the previously bonded devices that are most adjacent to the device being solder bonded.

### Array Characterisation

In normal operation of the print head, drive current to each laser is controlled according to whether the laser should be addressed to print a dot at any given time.

Thus, the drive current is switched on and off (or driven high and low either side of a switching threshold) according to the image to be printed.

The drive current required to produce a desired beam shape, size, intensity and energy distribution from any given laser element varies as a function of, for example, temperature in the laser element. Thus, in order to maintain a high degree of control over the spot shape, size, intensity and energy distribution from the laser arrays it is necessary to further modulate the drive currents supplied to the laser elements, i.e. in addition to the drive current switching referred to above.

Ideally, drive current to each of the laser elements is modulated independently as a function of optical feedback from each element in the array, which effectively ensures that the correct beam parameters are achieved for each laser element. To do this requires optical output sensing by, for example, a photodiode integrated into each laser element. This increases the cost of production and complexity.

As shown schematically in FIG. 6, another approach is to pre-characterise the laser array 60 by establishing the current drive modulation required for each laser element 61 in the array for a range of different operating temperatures. The characterisation data may then be stored in a look-up table 62 in a memory (e.g. EEPROM) which can be accessed in real time by a drive circuit 63 to determine the ideal drive parameters for each element 61 in the array 60, for a measured or assumed temperature of the print head.

In this arrangement, the print head includes a thermocouple 64 to measure the average head temperature in the array region. During manufacture or characterisation of the laser array 60, the individual lasers 61 are characterised for relevant properties, such as threshold etc, and this information is stored in the memory 62. Based on a mean temperature and the individual laser characteristics, the drive electronics 63 can then calculate individual drive conditions (such as drive current and switch on/switch off time) for each laser element 61. Use of customised drive conditions for each laser element 61 provides more control over the print quality, while being a relatively cost efficient implementation that is easily manufactured.

Thus, in the embodiment shown, the drive circuit 63 provides drive current to each laser element 61 in the array, according to two conditions. Firstly, the drive circuit separately addresses or drives each laser element 61 in the array 60 according to a desired print pattern provided by a print engine, e.g. pixel processor 65. The drive circuit incorporates a modulation circuit 66 for varying the drive current to each laser in the array according to a predetermined calibration algorithm that takes into account specific conditions prevailing in or relevant to each particular laser element. One or more of the drive circuit 63, memory 62 and modulation circuit 6 may be formed as an ASIC.

The calibration algorithm compensates for operating conditions, such as temperature of the print head, but may also take into account a particular current drive level required in order to achieve a particular colour of dot (or other special print characteristic) to be printed, as will be discussed later.

One or more temperature sensors 64 may be used, monitoring temperature in the print head, the array or the ASIC. The temperature sensor may reside in the laser array 60, ASIC or other part of the print head. Preferably, at least one temperature sensor 64 is in close proximity to the or each laser array 60. Rather than a look-up table 62, the control algorithm may be implemented by calculations performed in real time implemented in software or hardware. The algorithm is used to determine the individual drive currents so that each of the laser elements emits a selected power taking account the temperature of the laser element.

The algorithm may choose the drive current by estimating the temperature of individual laser elements based on a single temperature measurement by taking account of one or more of: (i) the measured temperature of the module and/or ASIC and/or the laser array; (ii) the drive history of each element; (iii) the drive history of adjacent elements and optionally other elements in the chip; the relative position of a drive element within the array. Conditions (ii) and (iii) may take into account whether the print pattern has recently demanded a high utilisation of a laser element, or only a low utilisation of the laser element. Where only a limited range of calibration data is present, interpolation may be used to obtain drive current modulation values.

The drive circuit 63 may be arranged to switch the laser elements on and off, by switching the laser current between a low level (which may be zero or non-zero) and a high level in response to the source of electronic printing data (e.g. pixel processor 65. Memory buffers may be provided between the pixel processor 65 and the drive circuit 63.

The apparatus described above in connection with FIG. 6 recognises that semiconductor laser diodes vary in performance with varying temperature, and seeks to compensate for such variability in performance by controlling drive current accordingly. Specifically, the laser threshold current (the electrical current at which lasing begins or turns on) tends to increase with increasing temperature and decreases with decreasing temperature. Also the slope efficiency (the optical power per amp or milliamp of applied current after the threshold current has been exceeded) tends to decrease with increasing temperature and increase with decreasing temperature.

Thus, for a given electrical current applied to the laser, the optical power emitted from the laser output facet will decrease as the temperature increases and vice-versa. As previously discussed, where the printed mark varies in optical density with incident optical power, a variation in emitted optical power with varying temperature is undesirable.

In another aspect of the invention, the emitted optical power is deliberately controlled to effect changes in the optical power according to a desired print colour or dot size. Some thermally sensitive inks in thermally sensitive print media change colour when heated to a threshold temperature. Two colour papers are available in the art (typically black and red). In these papers, the red ink is activated at a temperature below that of the black ink. Raising the temperature of the paper to the threshold for the red ink activates the red colour while raising the temperature to the black threshold value actives the red and black inks, but the black colour dominates. The principle may extend for multiple colours.

The principles described in connection with FIG. 6 can also be used to control modulation of the laser element outputs for different colours. In this case, the pixel processor 65 provides not only information relating to whether a dot is to be printed or not, but also the colour of the dot. The modulator and look-up table can also be used to determine drive current required for the given colour of dot.

A similar principle applies in respect of dot size, instead of colour.

Another way to effectively modulate power level is to use a single ‘on’ power level but to modulate it digitally by varying the on pulse width. In other words, the power modulation occurs in the time domain. In this arrangement, during normal operation, the drive circuit 63 is operative to switch the laser elements for a number of on-periods per pixel, the number of on-periods being varied by the modulator 66 according to the laser power print media heating effect) required for any given pixel. For example, for a pixel print rate of 1 kHz, the laser can be preferably pulsed at 10 kHz. For a first colour pixel, perhaps three pulses of the ten can be used and for the second colour pixel, all ten pulses being used. This digital modulation may also be implemented using the look-up table 62.

Another approach to varying spot energy density is to vary the speed of the print media past the print head.

Another approach to power modulation, e.g. for two or more colour printing, is to use two or more lasers focussed on the same points on the print media. For a first colour requiring lower power, only a single laser element is actuated, while for the second colour, both laser elements corresponding to the pixel to be printed are actuated.

An approach to eliminate the variation in power in semiconductor lasers is to actively monitor the temperature of the laser and use a feedback loop to a micro-controller that in turn controls a cooling/heating device. The control loop acts to maintain a constant laser temperature and consequently a constant emitted optical power. Other alternatives include monitoring the emitted optical power using a photodiode and a coupling device. The measured optical power is used to adjust the current applied to the laser and so maintain constant power. This approach has the disadvantage of requiring the use of photodiodes and coupling optics—both of which will add significantly to the device cost. In a laser array, photodiodes and coupling devices would be required for each laser element in the array. Devices that are capable of such cooling include thermoelectric coolers or Peltier pumps, but the cost of these components is significant. In addition they require significant additional electrical power to operate.

An alternative proposed here is to maintain the laser at a constant high temperature. This approach still achieves and maintains a constant temperature via feedback from a temperature sensor, but has the advantage of not requiring an expensive Peltier cooler. The elevated temperature is chosen such that the temperature exceeds that reached at the maximum ambient temperature and the maximum thermal dissipation within the device. If this is not the case, the device may exceed the set temperature under these conditions.

In a preferred arrangement, the print head includes a supplementary heat source (i.e. supplementary to that inherently formed by the laser elements and their operating circuitry, during normal operation thereof) that increases the temperature of the laser elements to a threshold temperature that is higher than normal ambient operating temperature of the laser elements. Depending upon the operational load on the laser elements, the supplementary heat source ‘tops up’ the temperature of the laser elements to the threshold temperature so that the elements operate constantly at the elevated threshold temperature.

In preferred embodiments this temperature is at least 10 degrees Centigrade above ambient. More preferably, the temperature of each element, each array, each carrier or the print head as a whole, is maintained at 50, 70 or 80 degrees Centigrade.

The supplementary heat source may comprise one or more separate heating elements on each laser element in the monolithic array, one or more heating elements on the array, one or more heating elements on each carrier, or one or more heating elements within the print head.

The supplementary heat source ensures that a substantially constant laser element temperature is maintained so that the laser element has a stable operating characteristic.

### Output Optics

Another aspect of the laser arrays for use as print heads for thermal print media is that the laser beams are focussed to produce a plurality of spots of the appropriate shape, size and distribution at the plane of the thermally sensitive print media being used. Beam focussing and shaping can be influenced or controlled not only by the laser element design and driving parameters, but also by appropriate optical elements positioned at or proximal to the optical outputs of the lasers in the array. The optical elements may include waveguides, lenses and windows positioned in the optical output path of the laser elements.

In preferred arrangements, the optical elements provide a degree of protection to the output facets of the laser elements. However, an important consideration in the design of print heads is the ability to keep the print head clean and clear of debris and deposits from the print media that will degrade the optical performance.

Another aspect of the invention is the provision of an automatic cleaning mechanism. As previously described, an advantage of optical delivery of thermal energy to the print media is that no contact between the print head and the print media is necessary. The method described here uses the print media itself to effect cleaning of the optical print head thereby reducing or eliminating the need for separate user cleaning of the system.

To automatically clean the optical print head, print media is provided with a specially modified ‘head cleaning portion’ that is thicker than the normal print media such that as the head cleaning portion is passed along the transport path past the optical head, the normal separation between the print head and the print media itself diminishes to a point where the print media effectively wipes the print head output elements (e.g. lenses or waveguides).

Thus, in a preferred embodiment, a roll of thermally sensitive paper has a first thickness and a head cleaning portion at the beginning or end of the roll that has a second thickness greater than the first thickness. The difference between the first and second thickness is adapted to be sufficient to reduce a normal separation distance from the print head to print media to zero, thereby enabling abrasive cleaning of the print head by the head cleaning portion of the print media.

The head cleaning portion of the print media may not only be thicker, but may also exhibit different surface properties, such as being softer, more fibrous, patterned, tacky etc, to aid the cleaning process. The head cleaning portion may be an additional “tab” that is stuck to the end of the print media roll.

In another arrangement, the print media transport mechanism may be adapted to periodically shift the transport path towards the print head such that the print media is brought into contact with the surface of the print head lens (or other optical output surface) to effect a wiping action on the print head. This could be effected at the beginning or end of a roll of paper, between printing runs or during a “setup” or “switch off” procedure.

Thus, in a general aspect, the method provides for automatically cleaning the print head by conveying the print media along a transport path that passes the print head, where the plane of the surface of the print media at the point where it passes the print head is separated from the output face of the print head by a predetermined distance during normal printing operations. Periodically, the plane of the surface of the print media is brought into contact with the output face of the print head, during conveyance of the print media along the transport path, in order to provide a mechanical wiping action to the output face of the print head. This periodical wiping can be effected by the head cleaning portion of the print media having a thickness which is greater than the thickness of the rest of the print media, or by temporarily displacing the transport path towards the print head.

In order to achieve the desired quality of mark, it is necessary to control the propagation of the light from the laser facet to the print media such that the size, shape and intensity profile of the optical energy on the print media meets a predetermined specification.

A laser beam will tend to diverge after it has exited the laser facet. The extent of this divergence, especially in the vertical plane (i.e. orthogonal to the plane of the laser array substrate) is such that the laser must be placed very close to the print media in order that the optical beam is within the required dimensions.

With reference to FIG. 7, a technique for confining the laser energy in the vertical dimension is shown. The laser array 31 is aligned with a slab of glass 70 such that the optical energy 71 enters the glass 70 at an input facet 72 and exits the glass at the opposite, output facet 73. The refractive index difference between the glass 70 and the surrounding air acts to confine the optical energy within the glass by total internal reflection. The input and output facets 72, 73 of the glass slab 70 may be coated with an anti-reflection coating to reduce losses in the optical energy when the beams enter and exit the glass slab. The length L of the glass slab (in the beam, or z-direction) is chosen such that the optical beams 71 diverge in the lateral horizontal direction (x-direction, as shown) to the extent that when they exit the glass slab 70 and are incident on the print medium 76, they are of the desired horizontal dimension. The thickness T of the glass slab 70 (in the vertical, or y-direction) is chosen to ensure that the vertical dimension of the optical spot when incident on the print media is of the required dimension. The glass slab 70 may be metallized on the top and bottom faces 74, 75 in order to improve optical confinement within the glass slab.

Thereby, the glass 70 forms an output waveguide which is adapted to focus each of the semiconductor laser 34 outputs 71 from the array 31 onto an image plane 76 that corresponds to the surface of print media travelling along a print media transport path. The length L of the output waveguide in the beam direction z is selected such that the beam divergence in the lateral direction x provides a desired spot dimension in x at the print media surface 76, and the thickness T of the output waveguide in the vertical dimension y is selected to provide a desired spot dimension in y at the print media. In other words, the length L and thickness T of the output waveguide are selected, for the given refractive index of the waveguide, in order to achieve a desired spot aspect ratio at the plane of the print media, i.e. for a given distance in z separating the output waveguide and the plane of the print media.

Another low cost technique for providing an output lens for a laser array is described with reference to FIG. 8. Traditional glass or plastic pre-formed optical lenses or systems can have a significant cost. In this embodiment, a transverse “bar” lens 82 is formed using optically transmissive epoxy. The laser array 31 with laser elements 34 is mounted onto the carrier 33 (together with any other laser arrays to form a compound array as previously described). When the laser arrays 31 are fixed mechanically and connected electrically, using either solder, epoxy or wire bonding techniques, a ‘filet’ or ‘bead’ of epoxy 82 is dispensed onto the facet 80 of the laser arrays 31 such that the filet forms a half rod-like structure 82. The epoxy is cured to harden it. The natural surface tension of the epoxy during dispense can provide a self aligning process, e.g. to a top edge 83 of the laser array 31. Alternatively, the epoxy filet 82 may have a thickness in the y dimension such that it completely covers the end facet 80 of the laser array, and is effectively aligned to the top and bottom edges 83, 84 of the laser array.

With reference to FIG. 9, in order to ensure that the epoxy 82 forms a lens structure 90 in which the semicircular profile 91 is correctly positioned in the y-direction relative to the optical waveguide 92 of the laser array 31 (which is below the surface 93 of the monolithic laser array 31), an additional glass block 94 of required thickness (in the y-direction) may be mounted on top of the laser array 31 to equalise the distance between the laser facet 95 (i.e. at the position of the laser waveguide 92) and each of the upper and lower edges 83, 84 of the structure. This may be important to enable correct manual or self alignment of the epoxy lens to the laser facet.

With reference to FIG. 10, this technique may also be used in conjunction with a glass window 100 applied to the laser facet 95 and the epoxy filet 82 applied to the glass 100. The glass window 100 may be of any suitable height to ensure that the epoxy filet 82 is correctly positioned with respect to the beam axis/laser waveguide 92. The expression ‘glass’ in this context is intended to encompass any suitable optically transmissive rigid material, preferable of a crystalline form.

The techniques of FIGS. 8, 9 and 10 may also be used with other non-epoxy, dispensable materials—e.g. silicone. In a general aspect, the material used to form the bead or filet could be any material that can be dispensed in a flowable form (e.g. under pressure from a dispensing nozzle) and which sets or cures to form a hardened bead or bar of optically transmissible material.

Each of the techniques of FIGS. 8, 9 and 10 may also be applied by forming the epoxy (or other material) filet by way of a moulding process. In this instance, the epoxy filet may be applied and moulded after application to the end facet of the laser array. Alternatively, the epoxy filet may be pre-moulded prior to application to the end facet of the laser array. Any suitable mouldable optically transmissive material may be used.

The moulded lens could also be extended to cover the top surface of the laser arrays and provide a degree of encapsulation.

It may be necessary or desirable to apply one or more additional materials to the surface of the laser arrays before the moulding process. For example a compliant material may be dispensed over the wire bonds to enable thermal expansion to occur without damage to the wire bonds.

Output waveguides and lenses may also be used to change the laser spot energy distribution from a conventional Gaussian distribution (across the x and y axes orthogonal to beam direction, z). By use of multimode diffractive output waveguides, it is possible to produce a ‘top-hat’ profile 120 (FIG. 12) of beam energy across the x- and y-axes, thereby producing printed dots that have sharp, well-defined edges, if this is a desirable characteristic. This can be achieved using a waveguide that excites as many transverse modes in the waveguide as possible. Alternatively, this may be achieved using diffractive optics such as binary or multilevel phase plates.

In other arrangements, a multimode diffractive waveguide or diffractive optics arrangement that produces a ‘bat-wing’ profile 121 of beam power across the x- and y-axes may be desirable. For example, a laser waveguide may be provided with an active region having a first width, and a passive region at the optical output end in the form of a 1×2 multimode interference coupler. The waveguide has a step increase in width from the active region to the passive region or within the passive region such that a single transverse mode supported in the active region is divided into two transverse modes in the passive region. By arranging that the Gaussian profiles 122 of each of the two modes supported in the passive region are overlapping to a large extent, an approximation to the bat-wing profile 121 of FIG. 12 is achieved, as shown.

The profiles in FIG. 12 represent the intensity distribution in the image plane as a function of x or y or both x and y. In one embodiment, the intensity distributions indicated are the same in x and y and for all axes therebetween, i.e. the spot shape 130 approximates to a circle as shown in FIG. 13a. In other embodiments, the intensity distribution in x may be wider than that in y, with a continuously variable spot dimension between the x and y axes, e.g. yielding an oval spot shape 131 as shown in FIG. 13b, or vice versa. In other embodiments, the diffractive optics may be configured to yield a rectangular spot shape 133 as shown in FIG. 13d, and more preferably a square spot shape 132 as shown in FIG. 13c. The aspect ratio of spot at the image plane (i.e. plane of the print media) may be arranged to have any suitable value, e.g. 1:1 in the case of spots 130, 132, or greater than/less than 1:1 in the case of spots 131, 133.

In a general sense the laser and output optics may be configured to provide an output spot having a substantially square or rectangular profile in the x-y plane, or a substantially circular or elliptical profile in the x-y plane. The x-y plane may be the image plane, or print media plane, orthogonal to the beam axis. In any of the above cases, the laser and output optics may also be configured to provide an output beam having a beam intensity profile across the x and/or y axes which has a square edge profile 120, a near-square edge profile 121 or a Gaussian edge profile 122, and with a flat top profile 120, bat wing top profile 121 or annular profile 122.

Another technique for varying effective spot size in the printer is to provide a small spot and, for the generation of larger dots on the print media, to deploy rapid relative translation of the print head and the print media. This can be done by dithering or vibrating either the print head or the print media using, for example, a piezoelectric actuator. For a typical print rate (laser switching frequency) of 1 kHz, a vibration frequency of 5 kHz or more is preferred. The vibration could be in either x- or y-direction, or both.

Thus, in a general aspect, there may be provided a mechanism for effecting a relative and periodic displacement (or ‘dithering’) of the output beams of the laser arrays relative to the print media, e.g. in at least one direction orthogonal to the laser beam optical axis. In the preferred embodiment, this is effected by rapid periodic mechanical displacement of the print head relative to the print media. In another embodiment, where the laser arrays in the print head are capable of electronic beam steering, the rapid periodic relative displacement of the output beams may be performed by an electronic beam steering control unit.

A number of aspects of laser array manufacture dictate a minimum spacing between laser elements, i.e. a minimum pitch of laser elements. These aspects include the width of the laser elements (e.g. as dictated by bond pad areas 25 or 26 of FIG. 2 and minimum wire bond distances dictated by wire bond equipment and the wire bond points 35 of FIG. 4).

With reference to FIG. 11, there is shown a technique for reducing the printed dot pitch from that which is possible with a given laser array pitch.

In a first arrangement of FIG. 11(a), the print head includes a laser array having optical spot outputs in a linear array 110 disposed relative to a print media or paper path having a transport direction 111 that is orthogonal to the linear array 110. The linear array 110 incorporates laser outputs 112 having a minimum laser separation distance in the array direction of, for example, 125 microns such that the minimum dot separation on the paper 113 is also 125 microns.

With reference to FIG. 11(b), in another arrangement, the laser array 114 is tilted in the printer with respect to the paper 113 such that the array direction is oblique to the transport direction 111. With laser outputs 117 having a pitch of 125 microns, this can produce a printed dot pitch 118 on the paper 113 in a direction orthogonal to the transport direction much less than the minimum pitch of the laser elements. The printed dot pitch is the laser element pitch multiplied by the cosine of the oblique angle of the array relative to the transport direction.

For example a 125 micron pitch laser array having its axis tilted 45 degrees to the transport axis produces a dot pitch on the paper 113 orthogonal to the transport axis of approximately 90 microns. A 60 degree array tilt gives a 62.5 micron pitch. Reducing the pitch on paper allows a reduced spot size on paper and a linear increase in the speed. For example, the 60 degree array tilt and 62 micron pitch will be twice as fast as the orthogonal array with 125 micron pitch due to increased power density. The cost is a slightly longer array (to cover the same print width) and a larger (squarer print head module) and more complex digital coding to control the on sequence of the lasers to produce drive currents for each laser element that takes into account the time delay required for triggering each laser element behind the leading element 116. However, in writing bar codes or black squares (shorter than an array length×sin angle) the power consumption will be lower than the non-tilted version.

FIG. 11a shows a plurality of tilted arrays 141, 142 shown as viewed along the z-axis (optical beam axis), e.g. as viewed from the plane of the print media. Each array has a lateral axis orthogonal to the beam axis and in the plane of the array. Each array is preferably mounted on a support structure 114. Using multiple tilted arrays on multiple support structures 114-1, 114-2, . . . 114-n etc in a row as shown in FIG. 11a offers a number of advantages. Each laser array on support structure 114 may comprise a single monolithic laser array 114 on the substrate. More preferably, however, each substrate 114 has a plurality of adjacent monolithic laser arrays 141-1, 141-2, . . . 141-n disposed thereon, using techniques described above. Each array substrate, e.g. 114-2 is positioned and aligned on the print head so that its ‘trailing end’ laser element 142 is immediately ‘adjacent’ in the x-direction to a ‘leading end’ laser element 143 of the next adjacent array substrate 114-3, although the trailing and laser elements 142 and leading end laser elements 143 of adjacent arrays are, as shown, separated in the y-direction. In a general aspect, it will therefore be understood that the lateral axes of the arrays 141 are aligned substantially parallel to one another but are not coaxial with one another.

The arrays and array substrates 114 thus form a ‘vane’ or ‘louver’ structure which is configured to deflect and allow passage of an air cooling flow 144 directed into the spaces 145 between the planes of the arrays 141. Significantly enhanced cooling of the laser arrays can thus be achieved in the otherwise densely packed print head. This has substantial advantages in maintaining a consistent temperature of each laser thereby improving the consistency of performance of elements in the array that might otherwise affect print consistency and print quality.

The tilted arrays can be successfully used to reduce the spot pitch otherwise available using existing laser arrays. However, an alternative strategy is to recognise that for a given achievable laser array pitch, it is possible to achieve a corresponding spot pitch by increasing the pitch of the laser arrays thereby improving yields, or allowing the use of higher powers while maintaining adequate heat dissipation. Increasing the laser pitch not only increases potential yields, drive currents and heat dissipation, but also eases die bonding processes allowing higher current bond wires and increased yields from the wire bond processes.

A further advantage of the louver arrangement is that the finite size of the monolithic arrays, carriers and/or support structures extending laterally beyond the leading and trailing laser elements 142 and 143 does not interfere with the desired lateral spacing of the laser elements. This is because the support structures can be disposed partially overlapping in planes defined by the laser arrays.

Individual arrays 141 and/or support structures 114 are preferably separately plugged into, and detachable from, a print head assembly allowing replacement of individual arrays where a laser element or monolithic array is faulty. This modular approach also improves yields and maintenance.

Drive circuitry to compensate for the displacement of successive laser elements in the y-direction (print media movement direction) may be located on the individual laser array circuitry, or more preferably on the print head itself. It will be understood that the function of such circuitry is to transfer some spatial domain print information into the temporal domain as a function of the relative displacement of the print media and the print head. In other words, the drive circuitry is configured to receive spatial print data corresponding to a spatial pattern to be printed, and to convert that spatial print data into combined spatial and temporal print data so as to activate individual laser elements as a function of (a) the velocity of the print media relative to the laser arrays in the transport direction, and (b) as a function of the angle of tilt of the arrays relative to the transport direction.

Other ways of controlling printed dot size and pitch are possible, and other techniques for controlling laser beam spot size and beam profile are possible.

Other embodiments are intentionally within the scope of the accompanying claims.

1. A print head comprising:
at least one monolithic array of semiconductor lasers;
a drive circuit for providing drive current to each laser element in the array, the drive circuit adapted to separately address each laser element in the array according to a desired print pattern;
an output waveguide adapted to focus each of the semiconductor laser outputs from the array onto an image plane that corresponds to a print media transport path.

2. The print head of claim 1 wherein the length L of the output waveguide in the beam direction z is selected such that the beam divergence in the lateral direction x provides a desired spot dimension in x at the print media, and the thickness T of the output waveguide in the vertical dimension y is selected to provide a desired spot dimension in y at the print media.

3. The print head of claim 2 wherein the ratio of spot dimension in x/y is 1.

4. A semiconductor laser device comprising an optical output facet and an output lens extending across at least a portion of the output facet, the output lens including a bead of optically transmissible material that is flowable during application to the output facet and that has set to form the output lens.

5. The laser device of claim 4 wherein the bead of material is self-aligned with at least one of a top or bottom edge of the laser facet.

6. The laser device of claim 4 further comprising a monolithic laser have a waveguide output at a facet thereof, and further including a glass window positioned over the waveguide output of the laser, the glass window thereby forming the output facet on which the bead lens is formed.

7. The laser device of claim 6 wherein the height of the monolithic laser and the glass window are different such that the bead of material is self-aligned to the optical output of the laser waveguide.

8. The laser device of claim 4 wherein the bead of material is epoxy or silicone.

9. The laser device of claim 4 wherein the bead of material is moulded to a desired shape during or after application to the laser output facet.

10. The laser device of 4 wherein the laser device is an array of lasers, and the bead of material extends across all laser outputs of the array.

11. The print head of claim 4 further including:
an optical element optically coupled to each laser element for producing a top-hat or bat-wing beam profile optical output suitable for activating a print medium.

12. The print head of claim 11 wherein the optical element defines a passive region of the laser waveguide.

13. The print head of claim 12 wherein the optical element comprises a 1×2 multimode interference coupler.

14. The print head of claim 11 wherein the optical element is a diffractive element.

15. The print head of claim 1 further including:
an optical element optically coupled to each laser element for producing a rectangular or square spot shape in an image plane orthogonal to the beam axis as optical output suitable for activating a print medium.

16. The print head of claim 1 further comprising
an optical element optically coupled to each laser element for producing a substantially circular or elliptical spot shape in an image plane orthogonal to the beam axis as an optical output suitable for activating a print medium.

17. (canceled)

18. A printing apparatus comprising:
an array of semiconductor lasers;
a transport mechanism for effecting relative displacement of the array of lasers and a thermally or optically sensitive print medium such that optical energy from the array of lasers can be directed onto the print medium as the print medium passes the laser array; and
dithering means for effecting a periodic relative displacement of the output beams of the array of lasers and the print medium;
wherein the dithering means comprises an electronic beam steering means for electronically effecting rapid periodic displacement of the output beams.

19. (canceled)

20. (canceled)
